(19) United States
(12) Patent Application Publication
(10) Pub. No.: US 2013/0322960 A1
(43) Pub. Date: Dec. 5, 2013

(54) LOCKING ASSEMBLY

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventors: Guan-Dong ZHAO, Shenzhen (CN); He-Li WANG, Shenzhen (CN)

(21) Appl. No.: 13/905,154

(22) Filed: May 30, 2013

(30) Foreign Application Priority Data
May 31, 2012 (CN) 2012101751460

(51) Int. Cl. H05K 5/02

(52) U.S. Cl. CPC H05K 5/0221
USPC 403/326

(57) ABSTRACT

A locking assembly includes a base, a hollow cover and an elastic arm. The cover includes a first protrusion and a second protrusion protruding from an inner sidewall of the cover, the first protrusion includes a upper face defining a inwardly curved surface. The elastic arm includes a latching post protruding from an end of the arm. The cover can be unlocked by a single press, where the latching post then abuts the bottom the first protrusion, or locked with a single press, where the latching post is then locked in the inwardly curved surface.

### TECHNICAL FIELD

The present disclosure relates to locking assemblies, and particularly to a locking assembly serving as a front cover of an electronic device.

### DESCRIPTION OF RELATED ART

Many foldable electronic devices include a base and a cover that is rotatably connected to the main base, such as portable optical disc players and notebook computers. In such electronic devices, there is a need to lock the cover to the main base. Although conventional connection mechanisms can meet basic needs, it is still desirable and useful to provide an electronic device with a new connection mechanism for locking the cover to the main base.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an assembled, isometric view of a locking assembly in accordance with an exemplary embodiment.

FIG. 2 is a schematic, exploded view of the locking assembly of FIG. 1.

FIG. 3 is an assembled, schematic view showing a base and an elastic arm of the locking assembly of FIG. 1.

FIG. 4 is a schematic view showing the elastic arm of the locking assembly of FIG. 1.

FIG. 5 is a schematic side-view showing the elastic arm of FIG. 4.

FIG. 6 is an assembled, cross-sectional view showing the base and the elastic arm of the locking assembly of FIG. 1.

FIG. 7 is a schematic view showing a cover of the locking assembly of FIG. 1.

FIG. 8 is a schematic, cross-sectional view of the cover of the locking assembly of FIG. 1.

FIG. 9 is a schematic view showing the locking assembly of FIG. 1 in a unlocked state.

FIG. 10 is a schematic view showing the locking assembly of FIG. 1 in a locked state.

FIG. 11 is a schematic view showing the locking assembly of FIG. 1 in a released state.

FIG. 12 is a schematic view showing the locking assembly of FIG. 1 in a resetting state.

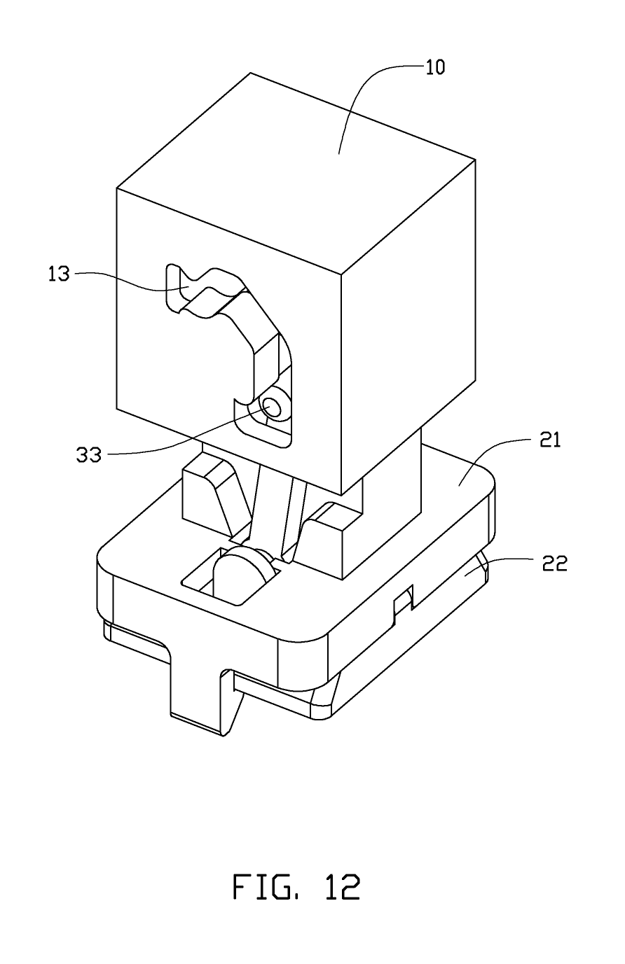

### DETAILED DESCRIPTION

The disclosure, including the accompanying, is illustrated by way of example and not by way of limitation. It should be noted that references to “an” or “one” embodiment in this disclosure are not necessarily to the same embodiment, and such references mean “at least one.”

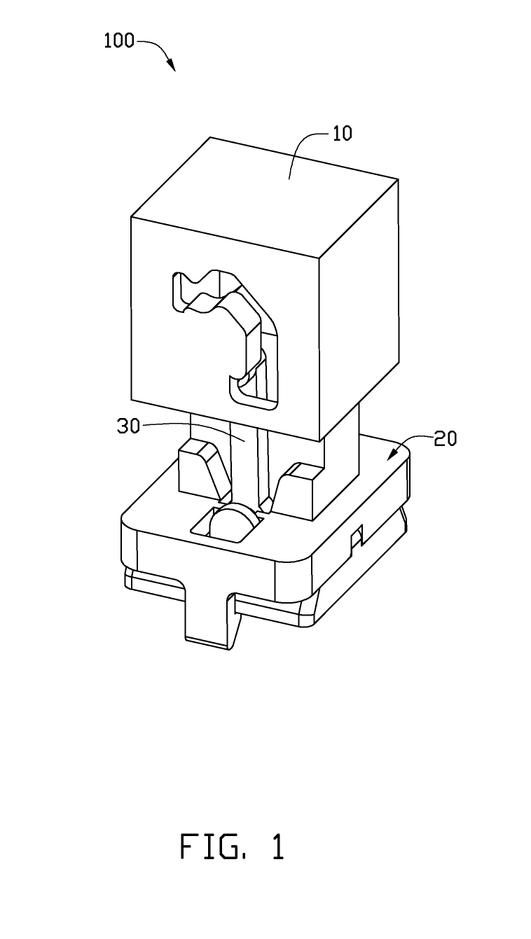

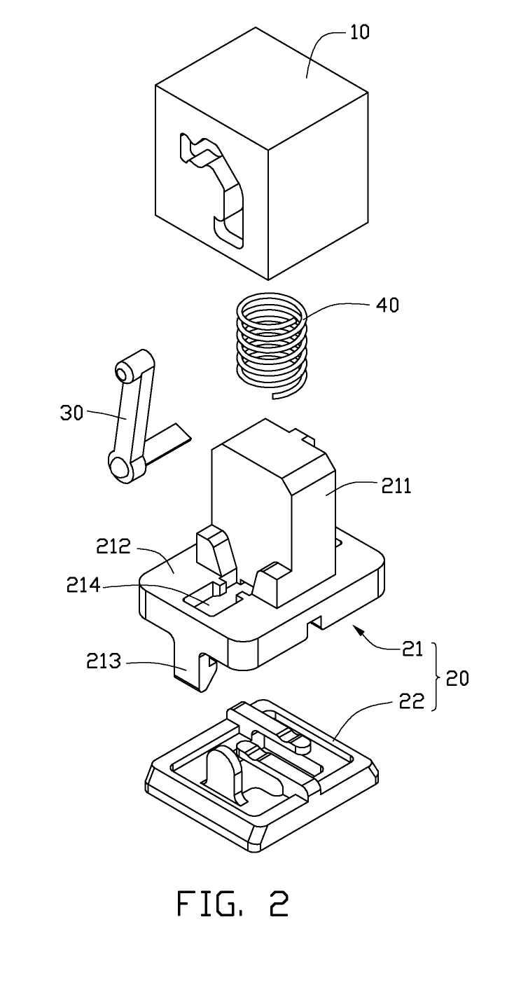

Referring to FIGS. 1 and 2, a locking assembly 100 of an electronic device is illustrated. The locking assembly 100 includes a cover 10, a base 20 and an elastic arm 30. The cover 10 is movably connected to the base 20 via the arm 30. A spring 40 is arranged between the cover 10 and the base 20, and applies a pushing force to the cover 10. In this embodiment, the electronic device is an optical disc player.

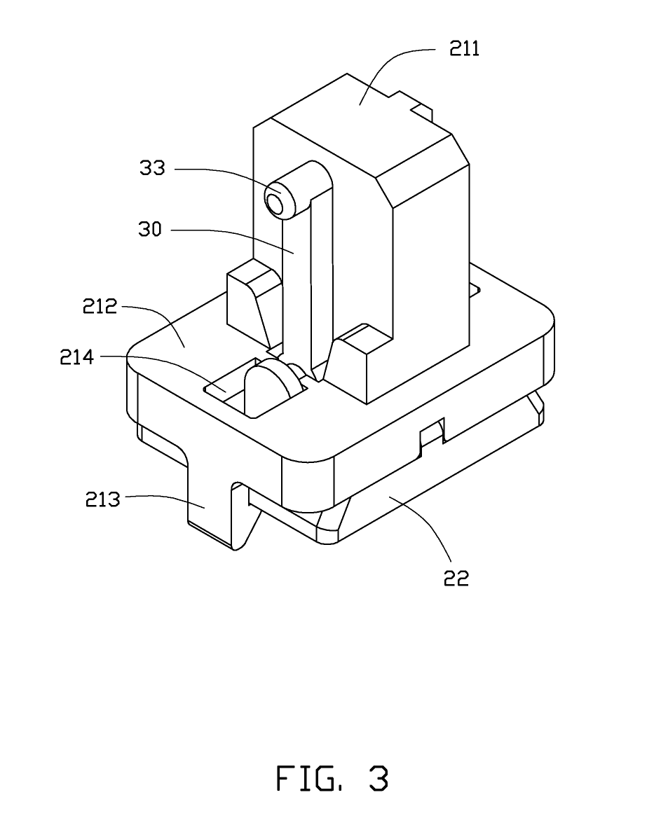

Referring to FIG. 3, the base 20 includes an upper base 21 and a lower base 22. The upper base 21 includes a bottom plate 212, a block 211 protruding from an upper surface of the bottom plate 212, and a pair of hooks 213 protruding from a lower surface of the bottom plate 212. The hooks 213 engage the edges of the lower base 22, thereby connecting the upper base 21 and the lower base 22 together. An opening 214 is defined in the bottom plate 212.

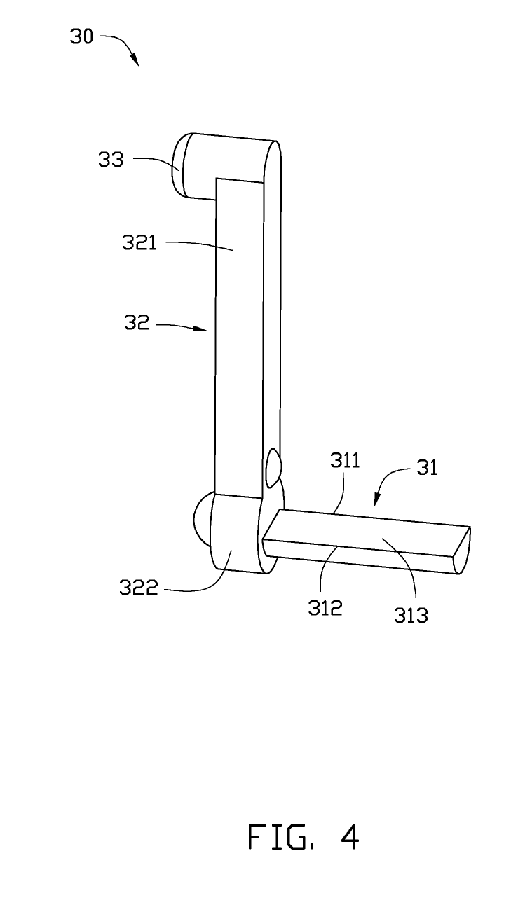

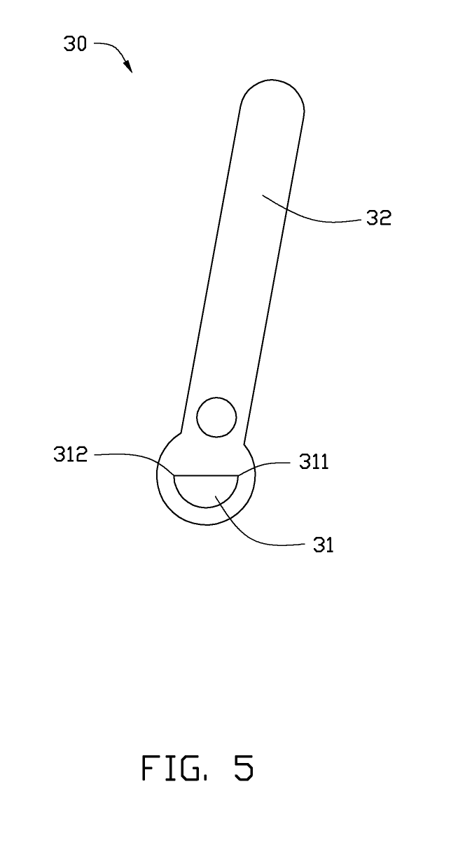

Referring to FIGS. 4 and 5, the elastic arm 30 includes a shaft 31 and a rotatable bar 32. The rotatable bar 32 includes a first end 321 and a second end 322 opposite to each other, and the shaft 31 is secured to the second end 322 of the rotatable bar 32. A latching post 33 protrudes from the first end 321 of the rotatable bar 32. The shaft 31 includes a semi-cylindrical lateral surface and a flat side surface 313 including a first edge 311 and a second edge 312. The shaft 31 and the rotatable bar 32 are perpendicular to each other, and the rotatable bar 32 is inclined with respect to the first edge 311 of the shaft 31. The elastic arm 30 is made of elastic material, such as plastic or rubber.

Referring to FIG. 5, an accommodating space 23 is formed between the upper base 21 and the lower base 22. The shaft 31 of the elastic arm 30 is retained in the accommodating space 23, and the rotatable bar 32 passes through the opening 214 of the bottom plate 212 and is exposed outside of the bottom plate 212. In this embodiment, the thickness of the shaft 31 is equal to the height of the accommodating space 23, in a normal state, and when the shaft 31 is vertically retained in the accommodating space 23, the rotatable bar 32 is deflected to the side of the first edge 311 with a certain angle as shown in FIG. 3.

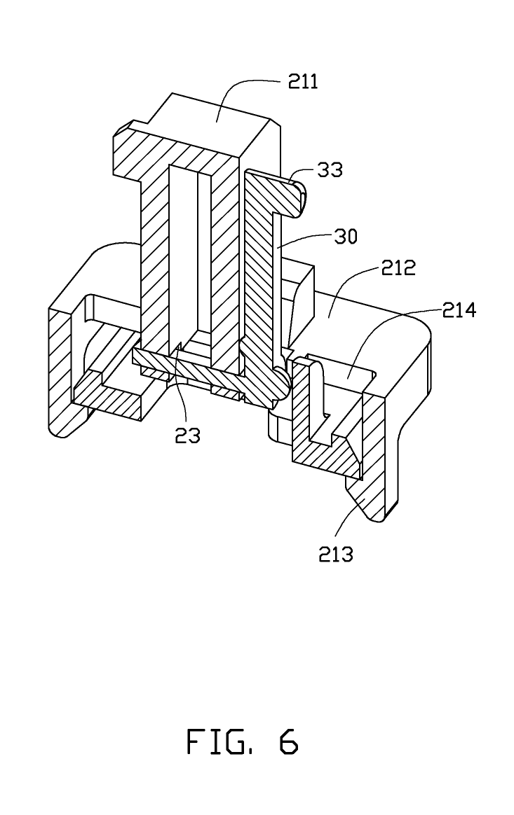

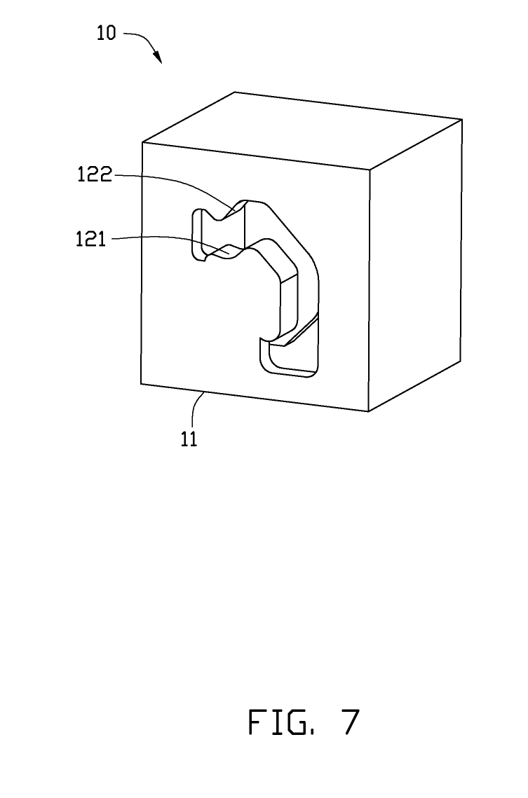

Referring to FIGS. 6 and 7, the cover 10 is a hollow housing having an inner space with an open end 11. In this embodiment, the cover 10 is a hollow cube. A first protrusion 121 and a second protrusion 122 protrude from an inner sidewall 12 of the cover 10, the first protrusion 121 is located below the second protrusion 122 and closer to the open end 11 than the second protrusion 122. The first protrusion 121 includes a upper face 1211 facing the second protrusion 122. The upper face 1211 further includes an inwardly curved surface 1213 and a first slanted surface 1214 connecting with the inwardly curved surface 1213. The first protrusion 121 further includes a lower, second slanted surface 1212, and extends from the bottom of the first protrusion 121 to the inwardly curved surface 1213 of the upper face 1211. The second protrusion 122 includes a lower face 1221 facing the first protrusion 121, and the lower face 1221 includes a third slanted surface 1222 located above the inwardly curved surface 1213. A guide slot 13 is formed between the upper face 1211 of the first protrusion 121 and the lower face 1221 of the second protrusion 122.

The rotatable bar 32 passes through the open end 11 of the cover 10, and is accommodated in the cover 10. The spring 40 is arranged between an inner top wall of the cover 10 and the block 211.

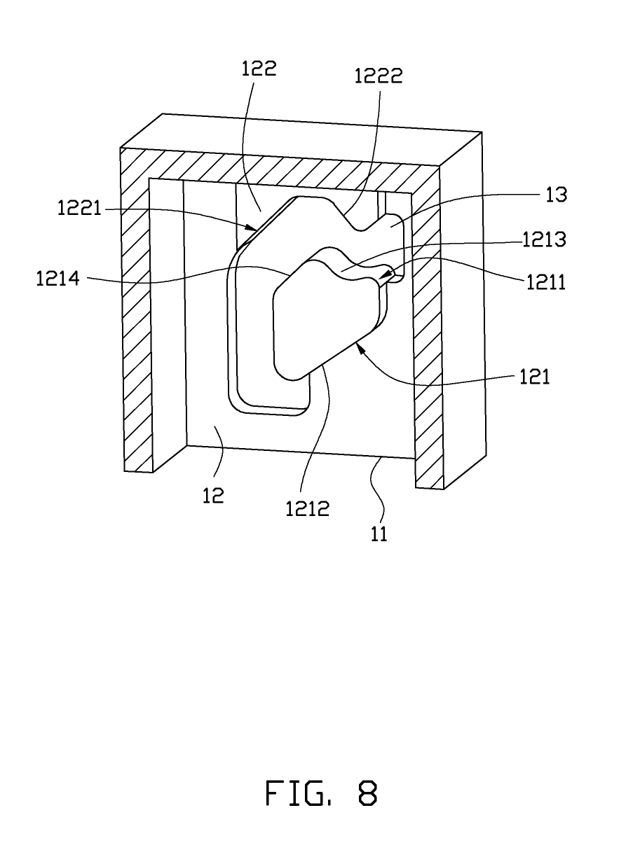

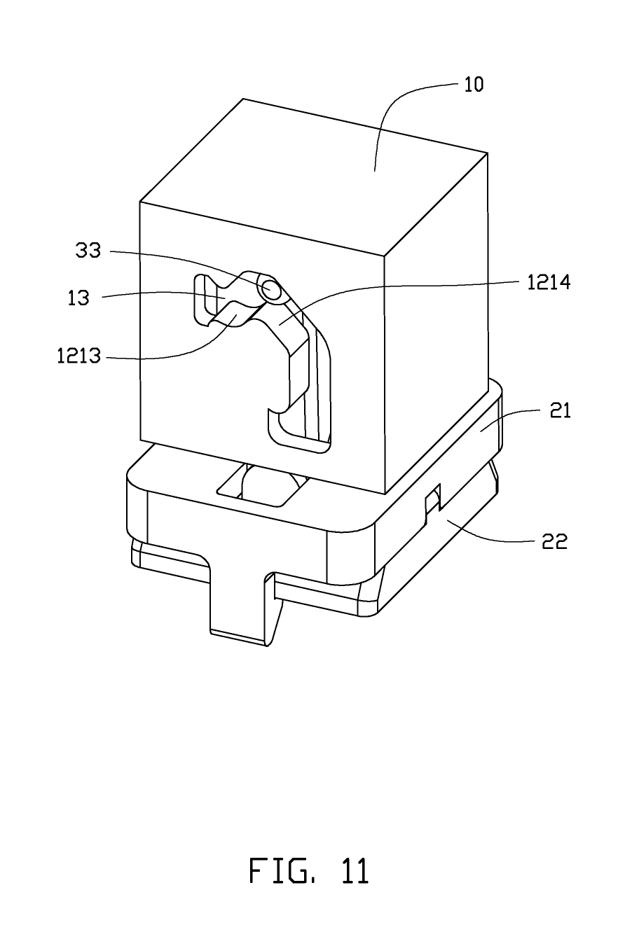

Various states of the locking assembly 100 are shown in FIGS. 8-11 for illustrating operating principles.

Referring to FIG. 8, the locking assembly is shown in an unlocked state. The cover 10 is movably connected to the base 20 and covers the block 211 of the upper base 21. The rotatable bar 32 is substantially vertical in the cover 10. The latching post 33 of the first end 321 of the rotatable bar 32 abuts against the bottom side of the second slanted surface 1212 of the first protrusion 121.

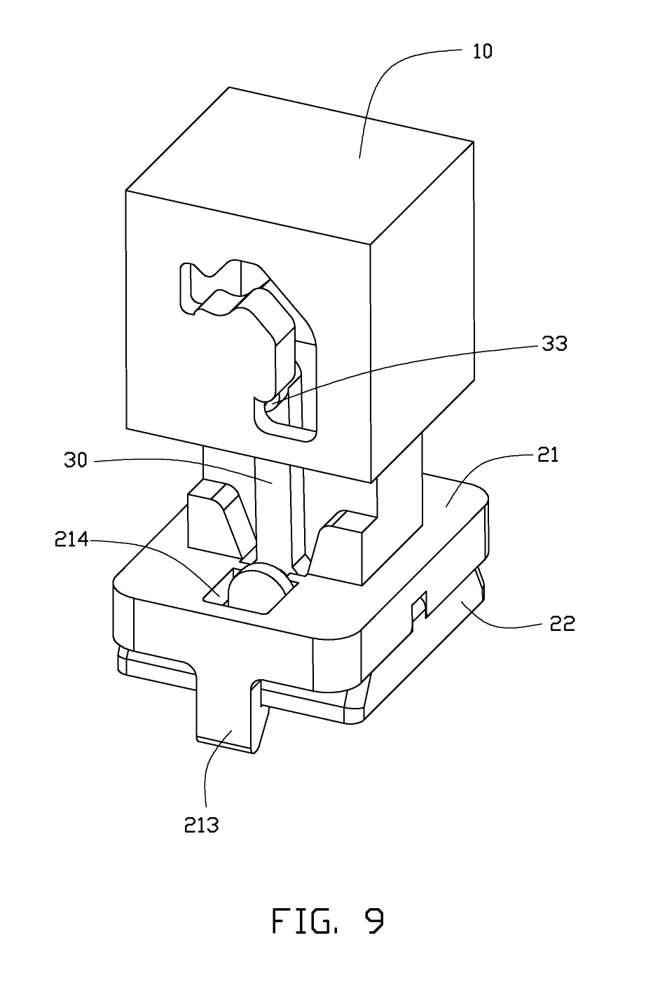

Referring to FIG. 9, the locking assembly 100 is shown in a locked state. When the unlocked cover 10 is pressed, the cover 10 moves toward the base 20. The latching post 33 of the first end 321 of the rotatable bar 32 is then deflected elastically, causing the latching post 33 to slide along the second slanted surface 1212. Finally, the latching post 33 disengages from the second slanted surface 1212 and slides into the guide slot 13, and is resisted by the lower face 1221 of the second protrusion 122. When the cover 10 is released, the cover 10 is urged upwards by the spring 40, the upper face 1211 of the first protrusion 121 then resists against the latching post 33. The elastic arm 30 rebounds, causing the latching post 33 to slide into the inwardly curved surface 1213 of the upper face 1211, thereby locking the cover 10 to the base 20.

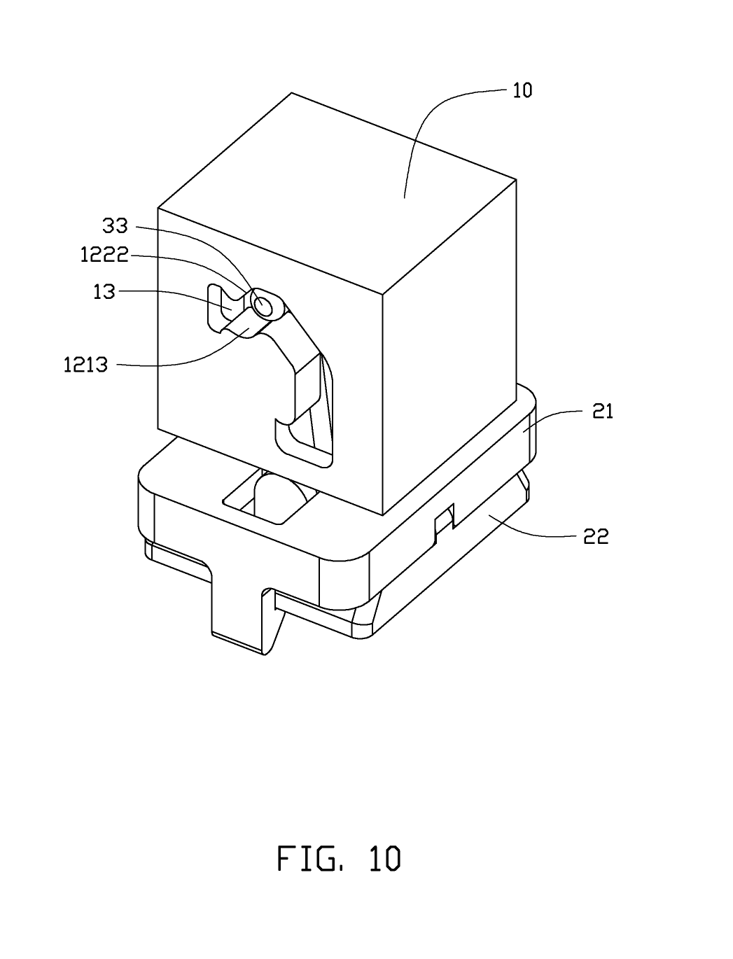

Referring to FIG. 10, when the closed and locked cover 10 is pressed, the cover 10 moves toward the base 20. The latching post 33 is then urged by the third slanted surface 1222 of the lower face 1221 of the second protrusion 122. The latching post 33 then deflects elastically, causing the latching post 33 to slide along the third slanted surface 1222. When the cover 10 is released, the cover 10 is urged by the spring 40 and moves upward, the first slanted surface 1214 of the upper face 1211 of the first protrusion 121 resists against the latching post 33. The latching post 33 then slides along the first slanted surface 1214 until it moves out of the guide slot 13. The latching post 33 then rebounds and abuts against the bottom side of the second slanted surface 1212 (FIG. 8).

With such configuration, the locking assembly 100 can be locked by pressing the cover 10 once, and the locking assembly 100 unlocked by pressing the cover 10 again.

It is to be understood, however, that even though numerous characteristics and advantages of the present disclosure have been set forth in the foregoing description, together with details of the structure and function of the present disclosure, the present disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A locking assembly comprising:
a base comprising an upper base defining an opening and a lower base engaged with the upper base, an accommodating space being formed between the upper base and the lower base, and an opening being defined in the upper base;
a hollow cover defining an inner space with an open end, the cover comprising an inner sidewall, a first protrusion and a second protrusion, the first and second protrusions protruding from the inner sidewall, the first protrusion comprising an upper face facing away from the open end, the upper face comprising an inwardly curved surface, wherein a guide slot is formed between the upper face of the first protrusion and a lower face of the second protrusion;
an elastic arm comprising a shaft, a rotatable bar perpendicularly connected to the shaft, and a latching post protruding from a free end of the rotatable bar, the shaft comprising a flat side surface having a first edge and an opposite second edge, wherein the rotatable bar is inclined with respect to the first edge of the shaft, the shaft is retained in the accommodating space, the rotatable bar passes through the opening and is exposed outside the upper base;
a spring arranged between the upper base and the cover, the spring being configured to apply a rebound force to the cover;
wherein the cover is reciprocally movable between an unlocked state where the rotatable bar is deflected to the first edge and the latching post abuts a lower face of the first protrusion, and a locked state where the latching post is lockingly engaged in the inwardly curved surface.

2. The locking assembly of claim 1, wherein the first protrusion further comprises a first slanted surface connected with the inwardly curved surface, the second protrusion comprises a lower face comprising a third slanted surface located above the inwardly curved surface.

3. The locking assembly of claim 1, wherein the cover further comprises a lower, second slanted surface defined on a lower face of the first protrusion.

4. The locking assembly of claim 1, wherein the upper base comprises a bottom plate, a block protruding from an upper surface of the bottom plate and a pair of hooks protruding from a lower surface of the bottom plate, the hooks engage edges of the lower base thus connecting the upper base and the lower base together, the spring is arranged between an inner top wall of the cover and the block.

5. The locking assembly of claim 1, wherein the shaft is a half-cylinder having a cylindrical lateral surface and the flat side surface.

6. The locking assembly of claim 1, wherein the elastic arm is made of elastic plastic or rubber.

7. The locking assembly of claim 1, wherein the cover is a hollow cube with the open end.
